(19) United States
(12) Patent Application Publication
(10) Pub. No.: US 2013/0127005 A1
(43) Pub. Date: May 23, 2013

(54) PHOTOVOLTAIC DEVICE AND METHOD OF MANUFACTURING THE SAME

(71) Applicants: Cho-Young Lee, Yongin-si (KR); Min-Seok Oh, Yongin-si (KR); Yun-Seok Lee, Yongin-si (KR); Nam-Kyu Song, Yongin-si (KR)

(72) Inventors: Cho-Young Lee, Yongin-si (KR); Min-Seok Oh, Yongin-si (KR); Yun-Seok Lee, Yongin-si (KR); Nam-Kyu Song, Yongin-si (KR)

(73) Assignee: Samsung SDI Co., Ltd., Yongin-si (KR)

(21) Appl. No.: 13/561,259

(22) Filed: Jul. 30, 2012

(30) Foreign Application Priority Data
Nov. 23, 2011 (KR) 10-2011-0123120

(51) Int. Cl. H01L 31/105; H01L 31/18

(52) U.S. Cl. 257/458; 438/87; 257/E31.061

(57) ABSTRACT

A photovoltaic device and a method of manufacturing the same are disclosed. In one embodiment, the device includes i) a semiconductor substrate, ii) a first conductive semiconductor layer formed on a first region of the semiconductor substrate and iii) a first transparent conductive layer formed on the first conductive semiconductor layer. The device may further include i) a second conductive semiconductor layer formed on a second region of the semiconductor substrate, ii) a second transparent conductive layer formed on the second conductive semiconductor layer and iii) a gap passivation layer interposed between i) the first layers and ii) the second layers, wherein the gap passivation layer has a thickness greater than the sum of the thicknesses of the first layers.

### RELATED APPLICATIONS

This application claims the benefit of Korean Patent Application No. 10-2011-0123120, filed on Nov. 23, 2011, in the Korean Intellectual Property Office, the disclosure of which is incorporated herein in its entirety by reference.

### BACKGROUND

1. Field

The described technology generally relates to photovoltaic devices and methods of manufacturing the same.

2. Description of the Related Technology

Unlike other sources of energy, solar energy is unlimited and environmentally friendly, thus becoming more and more important over time. A photovoltaic device such as a solar cell converts solar radiation to electric energy. Solar cells are categorized according to materials of light-absorbing layers.

Solar cells employing light-absorbing layers formed of silicon may be categorized into a crystalline (polycrystalline) wafer type solar cell and a thin-film type (amorphous, polycrystalline) solar cell. Furthermore, examples of other popular solar cells include a compound thin-film solar cell using CuInGaSe₂ (CIGS) or CdTe, a III-V group solar cell, a fuel-reactive solar cell, and an organic solar cell.

### SUMMARY

One inventive aspect is a photovoltaic device which includes a semiconductor substrate; a first conductive semiconductor layer which is formed on a first region of the rear surface of the semiconductor substrate and has a conductive type opposite to that of the semiconductor substrate; a first transparent conductive layer arranged on the first conductive semiconductor layer; a second conductive semiconductor layer which is formed on a second region of the rear surface of the semiconductor substrate and has a conductive type opposite to the first conductive type; a second transparent conductive layer arranged on the second conductive semiconductor layer; and a gap passivation layer which is arranged on the rear surface of the semiconductor substrate between the first region and the second region and has a thickness greater than a sum of the thicknesses of the first conductive semiconductor layer and the first transparent conductive layer.

The thickness of the gap passivation layer may be greater than a sum of the thicknesses of the second conductive semiconductor layer and the second transparent conductive layer.

The gap passivation layer may be arranged directly on the rear surface of the semiconductor substrate.

The photovoltaic device may further include a first intrinsic semiconductor layer arranged between the semiconductor substrate and the first conductive semiconductor layer, wherein the thickness of the gap passivation layer may be greater than a sum of the thicknesses of the first intrinsic semiconductor layer, the first conductive semiconductor layer, and the first transparent conductive layer.

The photovoltaic device may further include a second intrinsic semiconductor layer arranged between the semiconductor substrate and the second conductive semiconductor layer, wherein the thickness of the gap passivation layer may be greater than a sum of the thicknesses of the second intrinsic semiconductor layer, the second conductive semiconductor layer, and the second transparent conductive layer.

A width of the gap passivation layer may be from about 0.5 μm to about 500 μm.

The maximum width of the gap passivation layer may be 100 μm.

The thickness of the gap passivation layer may be from about 200 Å to about 3000 Å.

The semiconductor substrate may include crystalline silicon, and the first conductive semiconductor layer and the second conductive semiconductor layer may include amorphous silicon.

The gap passivation layer may include at least one of silicon oxide (SiOₓ) and silicon oxynitride (SiOₓN_{y}).

Another aspect is a method of manufacturing a photovoltaic device, the method including opening a first region in a passivation layer formed on the rear surface of a crystalline semiconductor substrate; sequentially forming a first intrinsic semiconductor layer, a first conductive semiconductor layer, and a first transparent conductive layer on the rear surface of the semiconductor substrate including the passivation layer with the opened first region; forming a first etch resist on the passivation layer except a second region that is a first distance apart from the first region; opening the second region of the passivation layer by etching the passivation layer by using the first etch resist as an etch mask; removing the first etch resist; sequentially forming a second intrinsic semiconductor layer, a second conductive semiconductor layer, and a second transparent conductive layer on the rear surface of the semiconductor substrate including the passivation layer with the opened second region; forming a second etch resist to cover the second region; etching the second intrinsic semiconductor layer, the second conductive semiconductor layer, and the second transparent conductive layer by using the second etch resist as an etch mask; and removing the second etch resist.

In the step of sequentially forming the first intrinsic semiconductor layer, the first conductive semiconductor layer, and the first transparent conductive layer, the first intrinsic semiconductor layer, the first conductive semiconductor layer, and the first transparent conductive layer may be formed, such that a sum of thicknesses of the first intrinsic semiconductor layer, the first conductive semiconductor layer, and the first transparent conductive layer is less than a thickness of the passivation layer, and, in the step of sequentially forming the second intrinsic semiconductor layer, the second conductive semiconductor layer, and the second transparent conductive layer, the second intrinsic semiconductor layer, the second conductive semiconductor layer, and the second transparent conductive layer may be formed, such that a sum of thicknesses of the second intrinsic semiconductor layer, the second conductive semiconductor layer, and the second transparent conductive layer is less than the thickness of the passivation layer.

The step of opening the second region may include etching the first transparent conductive layer not covered by the first etch resist; etching the first conductive semiconductor layer and the first intrinsic semiconductor layer below the etched first transparent conductive layer; and etching the passivation layer below the etched first intrinsic semiconductor layer and the first conductive semiconductor layer, and the step of etching the first conductive semiconductor layer and the first intrinsic semiconductor layer may include etching the first conductive semiconductor layer and the first intrinsic semiconductor layer arranged between the passivation layer and the first etch resist in the lateral direction.

The step of etching the second intrinsic semiconductor layer, the second conductive semiconductor layer, and the second transparent conductive layer may include etching the second transparent conductive layer not covered by the second etch resist; and etching the second conductive semiconductor layer and the second intrinsic semiconductor layer below the etched second transparent conductive layer, and the step of etching the second conductive semiconductor layer and the second intrinsic semiconductor layer may include etching the second conductive semiconductor layer and the second intrinsic semiconductor layer arranged between the passivation layer and the second etch resist in the lateral direction.

The first intrinsic semiconductor layer, the first conductive semiconductor layer, the second intrinsic semiconductor layer, and the second conductive semiconductor layer may include amorphous silicon, and the passivation layer may include at least one of silicon oxide (SiOₓ) and silicon oxynitride (SiOₓN_{y}).

Another aspect is a method of manufacturing a photovoltaic device, the method including opening a first region and a second region that is a first distance apart from the first region in a passivation layer formed on the rear surface of a crystalline semiconductor substrate; sequentially forming a first conductive semiconductor layer and a first transparent conductive layer on the rear surface of the semiconductor substrate including the passivation layer with the opened first and second regions; forming a first etch resist to cover the first region; etching the first conductive semiconductor layer and the first transparent conductive layer by using the first etch resist as an etch mask; removing the first etch resist; sequentially forming a second conductive semiconductor layer and a second transparent conductive layer on the rear surface of the semiconductor substrate from which the first etch resist is removed; forming a second etch resist to cover the second region; etching the second conductive semiconductor layer, and the second transparent conductive layer by using the second etch resist as an etch mask; and removing the second etch resist.

The step of sequentially forming the first conductive semiconductor layer and the first transparent conductive layer may further include forming a first intrinsic semiconductor layer between the semiconductor substrate and the first conductive semiconductor layer, and the step of sequentially forming the second conductive semiconductor layer and the second transparent conductive layer may further include forming a second intrinsic semiconductor layer between the semiconductor substrate and the second conductive semiconductor layer.

The step of etching the first conductive semiconductor layer and the first transparent conductive layer may include etching the first transparent conductive layer not covered by the first etch resist; and etching the first conductive semiconductor layer below the etched first transparent conductive layer, and the step of etching the first conductive semiconductor layer may include etching the first conductive semiconductor layer arranged between the passivation layer and the first etch resist in the lateral direction.

The step of etching the second conductive semiconductor layer and the second transparent conductive layer may include etching the second transparent conductive layer not covered by the second etch resist; and etching the second conductive semiconductor layer below the etched second transparent conductive layer, and the step of etching the second conductive semiconductor layer may include etching the second conductive semiconductor layer arranged between the passivation layer and the second etch resist in the lateral direction.

The first intrinsic semiconductor layer, the first conductive semiconductor layer, the second intrinsic semiconductor layer, and the second conductive semiconductor layer may include amorphous silicon. The passivation layer may include at least one of silicon oxide (SiOₓ) and silicon oxynitride (SiOₓN_{y}).Another aspect is a photovoltaic device comprising: a semiconductor substrate; a first conductive semiconductor layer formed on a first region of the semiconductor substrate, wherein the first conductive semiconductor layer has a conductive type opposite to that of the semiconductor substrate; a first transparent conductive layer formed on the first conductive semiconductor layer; a second conductive semiconductor layer formed on a second region of the semiconductor substrate, wherein the second conductive semiconductor layer has a conductive type opposite to the first conductive type; a second transparent conductive layer formed on the second conductive semiconductor layer; and a gap passivation layer interposed between i) the first layers and ii) the second layers, wherein the gap passivation layer has a thickness greater than the sum of the thicknesses of the first layers.

In the above device, the thickness of the gap passivation layer is greater than the sum of the thicknesses of the second layers. In the above device, the gap passivation layer contacts the semiconductor substrate. The above device further comprises a first intrinsic semiconductor layer interposed between the semiconductor substrate and the first conductive semiconductor layer, wherein the thickness of the gap passivation layer is greater than the sum of the thicknesses of the first layers. The above device further comprises a second intrinsic semiconductor layer interposed between the semiconductor substrate and the second conductive semiconductor layer, wherein the thickness of the gap passivation layer is greater than the sum of the thicknesses of the second layers.

In the above device, the width of the gap passivation layer is from about 0.5 μm to about 500 μm. In the above device, the gap passivation layer contacts i) the first and second conductive semiconductor layers and ii) the first and second transparent conductive layers. In the above device, the thickness of the gap passivation layer is from about 200 Å to about 3000 Å. In the above device, the semiconductor substrate comprises crystalline silicon, and wherein at least one of the first and second conductive semiconductor layers comprises amorphous silicon. In the above device, the gap passivation layer is formed of at least one of silicon oxide (SiOₓ) and silicon oxynitride (SiOₓN_{y}).

Another aspect is a method of manufacturing a photovoltaic device, the method comprising: forming a passivation layer over a semiconductor substrate; opening a first region of the passivation layer such that a first portion of the semiconductor substrate is exposed; sequentially forming a first intrinsic semiconductor layer, a first conductive semiconductor layer, and a first transparent conductive layer on the first exposed portion of the semiconductor substrate and the passivation layer; forming a first etch resist on the passivation layer except for a second region spaced apart from the first region; opening the second region of the passivation layer based on etching of the passivation layer with the use of the first etch resist as an etch mask such that a second portion of the semiconductor substrate is exposed; removing the first etch resist; sequentially forming a second intrinsic semiconductor layer, a second conductive semiconductor layer, and a second transparent conductive layer on i) the second exposed portion of the semiconductor substrate, ii) the passivation layer and iii) the first transparent conductive layer; forming a second etch resist to cover the second region; etching the second intrinsic semiconductor layer, the second conductive semiconductor layer, and the second transparent conductive layer with the use of the second etch resist as an etch mask; and removing the second etch resist.

In the above method, the first intrinsic semiconductor layer, the first conductive semiconductor layer, and the first transparent conductive layer are sequentially formed such that the sum of the thicknesses of the first layers is less than the thickness of the passivation layer, and wherein the second intrinsic semiconductor layer, the second conductive semiconductor layer, and the second transparent conductive layer are sequentially formed such that the sum of the thicknesses of the second layers is less than the thickness of the passivation layer.

In the above method, the opening of the second region comprises: etching a portion of the first transparent conductive layer which is not covered by the first etch resist; laterally etching portions of the first semiconductor layers which are interposed between the passivation layer and the etched portion of the first transparent conductive layer; and etching a portion of the passivation layer which is formed substantially directly below the etched portions of the first semiconductor layers.

In the above method, the first semiconductor layers are etched more than the first transparent conductive layer. In the above method, the etching of the second layers comprises: etching a portion of the second transparent conductive layer which is not covered by the second etch resist; and laterally etching portions of the second semiconductor layers, which are interposed between the passivation layer and the etched portion of the second transparent conductive layer, wherein the second semiconductor layers are etched more than the first transparent conductive layer.

Another aspect is a method of manufacturing a photovoltaic device, the method comprising: providing a passivation layer over a semiconductor substrate; opening first and second regions of the passivation layer such that first and second portions of the semiconductor substrate are exposed, wherein the second region is spaced apart from the first region; sequentially forming a first conductive semiconductor layer and a first transparent conductive layer on the first and second exposed portions of the semiconductor substrate and the passivation layer; forming a first etch resist to cover the first region; etching the first conductive semiconductor layer and the first transparent conductive layer with the use of the first etch resist as an etch mask; removing the first etch resist; sequentially forming a second conductive semiconductor layer and a second transparent conductive layer on i) the second exposed portion of the semiconductor substrate, ii) the passivation layer and iii) the first transparent conductive layer; forming a second etch resist to cover the second region; etching the second conductive semiconductor layer, and the second transparent conductive layer with the use of the second etch resist as an etch mask; and removing the second etch resist.

In the above method, the first conductive semiconductor layer and the first transparent conductive layer are sequentially formed such that the sum of the thicknesses of the first layers is less than the thickness of the passivation layer, and wherein the second conductive semiconductor layer and the second transparent conductive layer are sequentially formed, such that the sum of the thicknesses of the second layers is less than the thickness of the passivation layer. In the above method, the etching of the first layers comprises: etching a portion of the first transparent conductive layer which is not covered by the first etch resist; and laterally etching a portion of the first conductive semiconductor layer formed between the etched portion of the first transparent conductive layer and the passivation layer.

In the above method, the first conductive semiconductor layer is etched more than the first transparent conductive layer. In the above method, the etching of the second layers comprises: etching a portion of the second transparent conductive layer which is not covered by the second etch resist; and laterally etching a portion of the second conductive semiconductor layer formed between the etched portion of the second transparent conductive layer and the passivation layer, wherein the second conductive semiconductor layer is etched more than the first transparent conductive layer.

### BRIEF DESCRIPTION OF THE DRAWINGS

FIG. 1 is a schematic sectional view of a photovoltaic device according to an embodiment.

FIG. 2 is a graph showing open circuit voltages (Voc) according to thicknesses of a photovoltaic device according to an embodiment.

FIGS. 3 and 4 are schematic sectional views of photovoltaic devices according to other embodiments.

FIGS. 5 through 17 are schematic sectional views showing steps of the method of manufacturing a photovoltaic device according to an embodiment.

FIGS. 18 through 30 are schematic sectional views showing steps of the method of manufacturing a photovoltaic device according to another embodiment.

### DETAILED DESCRIPTION

Embodiments will now be described more fully with reference to the accompanying drawings. It will be understood that although the terms first and second are used herein to describe various elements, these elements should not be limited by these terms. These terms are only used to distinguish one element from another element.

It will be understood that when an element or layer is referred to as being “on” another element or layer, the element or layer can be directly on another element or layer or intervening elements or layers. In contrast, when an element is referred to as being “directly on” another element or layer, there are no intervening elements or layers present.

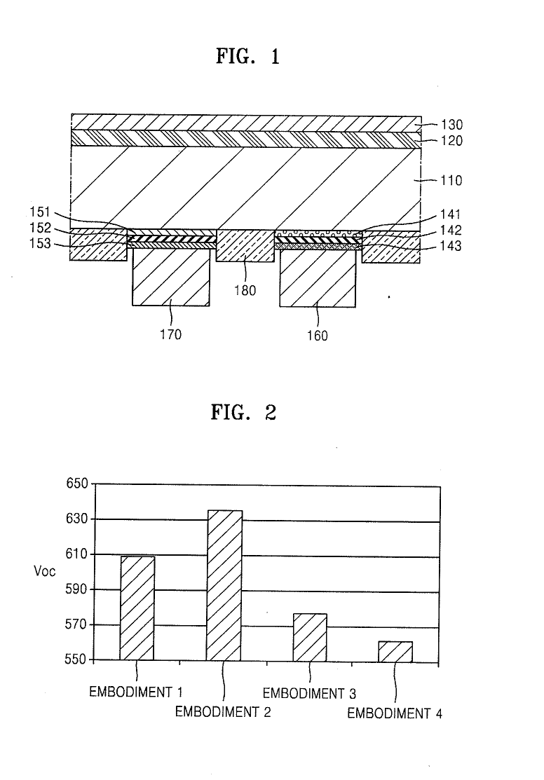

FIG. 1 is a schematic sectional view of a photovoltaic device according to an embodiment.

Referring to FIG. 1, the photovoltaic device includes a semiconductor substrate 110, a front (or first) passivation film 120, an anti-reflection film 130, first and second intrinsic semiconductor layers 141 and 151, first and second conductive semiconductor layers 142 and 152, first and second transparent conductive layers 143 and 153, first and second metal electrodes 160 and 170, and a gap passivation layer 180.

The semiconductor substrate 110 may include a front (or first) surface, which is a light-receiving surface, and a rear (or second) surface, which is opposite to the front surface. The first and second metal electrodes 160 and 170, which are, for example, emitter and base electrodes, respectively, may be formed on the rear surface of the semiconductor substrate 110 to form a back contact. The front surface of the semiconductor substrate 110 may function as a light-receiving surface without including an electrode structure. Therefore, an amount of valid incident light may be increased, light loss may be reduced, and high output power may be acquired.

The semiconductor substrate 110 may include a crystalline silicon substrate. For example, the semiconductor substrate 110 may include a monocrystalline silicon substrate or a polycrystalline silicon substrate. The semiconductor substrate 110 may include an n-type impurity. The n-type impurity may include a group V chemical element, such as phosphor (P) or arsenic (As).

The front passivation film 120 may be formed on the front surface of the semiconductor substrate 110. The front passivation film 120 may improve the efficiency of collecting carriers generated by the semiconductor substrate 110 by preventing surface re-combination of the carriers. For example, the front passivation film 120 may reduce surface re-combination loss due to surface combinations on the semiconductor substrate 110 and improve the efficiency of collecting carriers. For example, the front passivation film 120 may be formed of silicon oxide (SiOₓ), or silicon nitride (SiNₓ).

Alternatively, the front passivation film 120 may be formed as a semiconductor film doped with an impurity. For example, the front passivation film 120 may be an amorphous silicon doped with an impurity. The front passivation film 120 may include amorphous silicon doped with the same impurity as with which the semiconductor substrate 110 is doped, more densely as compared to the semiconductor substrate 110. In this case, due to the difference between concentrations of the impurities of the semiconductor substrate 110 and the front passivation film 120, a potential barrier is formed, and thus, re-combination and decomposition of electrons and holes near the front surface of the semiconductor substrate 110 may be prevented.

The anti-reflection film 130 may be formed on the front passivation film 120. The anti-reflection film 130 prevents light absorption loss of the photovoltaic device by reflecting light during the incidence of sunlight, and thus, the efficiency of the photovoltaic device may be improved. The anti-reflection film 130 is phototransmissive and may include silicon oxide (SiOₓ), silicon nitride (SiNₓ), silicon oxynitride (SiOₓN_{y}), etc. Alternatively, the anti-reflection film 130 may include titanium oxide (TiOₓ), zinc oxide (ZnO), zinc sulfide (ZnS), etc. The anti-reflection film 130 may include a single layer or a plurality of layers.

In the present embodiment, the front passivation film 120 and the anti-reflection film 130 are individually formed on the front surface of the semiconductor substrate 110. However, a single layer of a silicon nitride (SiNₓ) film, which may function as both the front passivation film 120 and the anti-reflection film 130, may be formed. Alternatively, a single layer of a hydrogenated silicon nitride (SiN:H) film may be used.

Semiconductor layers having different conductive types are formed in a first region and a second region of the rear surface of the semiconductor substrate 110, respectively . The first intrinsic semiconductor layer 141, the first conductive semiconductor layer 142, and the first transparent conductive layer 143 are formed in the first region of the rear surface of the semiconductor substrate 110. The second intrinsic semiconductor layer 151, the second conductive semiconductor layer 152, and the second transparent conductive layer 153 are formed in the second region of the rear surface of the semiconductor substrate 110. The first and second intrinsic semiconductor layers 141 and 151 may be formed on the rear surface of the semiconductor substrate 110 to have a width from about 10 μm to about 2000 μm.

The first intrinsic semiconductor layer 141 is formed on the first region of the rear surface of the semiconductor substrate 110 and may be formed of intrinsic amorphous silicon. The first intrinsic semiconductor layer 141 may not be doped with an impurity or may be doped with a small amount of an impurity.

The first intrinsic semiconductor layer 141 passivates the rear surface of the semiconductor substrate 110 and may improve interface characteristics between the crystalline semiconductor substrate 110 and the first conductive semiconductor layer 142 including amorphous silicon.

In the present embodiment, the first intrinsic semiconductor layer 141 is arranged between the semiconductor substrate 110 and the first conductive semiconductor layer 142. However, the first intrinsic semiconductor layer 141 may be omitted.

The first conductive semiconductor layer 142 is formed on the first intrinsic semiconductor layer 141 and has a conductive type opposite to that of the semiconductor substrate 110. Therefore, a p-n junction may be formed. For example, the first conductive semiconductor layer 142 may be doped with a p-type impurity, which is an opposite conductive type of the n-type semiconductor substrate 110.

The first transparent conductive layer 143 may be formed on the first conductive semiconductor layer 142, interconnect the first conductive semiconductor layer 142 and the first metal electrode 160, and reduce ohmic contact therebetween. The first transparent conductive layer 143 may be formed as a transparent conductive film (TCO), formed of, for example, indium tin oxide (ITO), indium zinc oxide (IZO) or zinc oxide (ZnO). The first transparent conductive layer 143 may be formed to have a thickness from about 100 Å to about 2000 Å.

The first metal electrode 160 is formed on the first transparent conductive layer 143 and may include silver (Ag), gold (Au), copper (Cu), aluminum (Al), and an alloy thereof. The first metal electrode 160 may include finger electrodes for collecting carriers and a busbar which is connected to the finger electrodes and forms an interconnection to outside.

The second intrinsic semiconductor layer 151 is formed on the second region of the rear surface of the semiconductor substrate 110 and may be formed of intrinsic amorphous silicon. The second intrinsic semiconductor layer 151 may not be doped with an impurity or may be doped with a small amount of an impurity.

The second intrinsic semiconductor layer 151 passivates the rear surface of the semiconductor substrate 110 and may improve interface characteristics between the crystalline semiconductor substrate 110 and the second conductive semiconductor layer 152 including amorphous silicon.

In the present embodiment, the second intrinsic semiconductor layer 151 is arranged between the semiconductor substrate 110 and the second conductive semiconductor layer 152. However, the second intrinsic semiconductor layer 151 may be omitted.

The second conductive semiconductor layer 152 is formed on the second intrinsic semiconductor layer 151 and has the same conductive type as the semiconductor substrate 110. For example, the second conductive semiconductor layer 152 may be doped with an n-type (or p-type) impurity. The second conductive semiconductor layer 152 may be more densely doped with an impurity than the semiconductor substrate 110 and may form a back surface field (BSF) to prevent re-combination of carriers generated by the semiconductor substrate 110.

The second transparent conductive layer 153 may be formed on the second conductive semiconductor layer 152, interconnect the second conductive semiconductor layer 152 and the second metal electrode 170, and reduce ohmic contact therebetween. The second transparent conductive layer 153 may be formed as a TCO, formed of, for example, ITO, IZO or ZnO. The second transparent conductive layer 153 may be formed to have a thickness from about 100 Å to about 2000 Å.

The second metal electrode 170 is formed on the second transparent conductive layer 153 and may include silver (Ag), gold (Au), copper (Cu), aluminum (Al), and an alloy thereof. The second metal electrode 170 may include finger electrodes for collecting carriers and a busbar which is connected to the finger electrodes and forms an interconnection to external units or devices.

In one embodiment, the gap passivation layer 180 is formed between the first and second regions of the semiconductor substrate 110 and is formed directly on the rear surface of the semiconductor substrate 110. The gap passivation layer 180 prevents the semiconductor substrate 110 from being exposed to outside the photovoltaic device or the environment. Therefore, the gap passivation layer 180 may prevent re-combination and decomposition of electrons and holes.

The gap passivation layer 180 may include at least one of silicon oxide (SiOₓ) and silicon oxynitride (SiOₓN_{y}). The gap passivation layer 180 may include one or more layers.

The thickness of the gap passivation layer 180 may be greater than the sum of the thicknesses of layers formed on either side of the gap passivation layer 180. For example, the thickness of the gap passivation layer 180 may be greater than the sum of the thicknesses of the first intrinsic semiconductor layer 141, the first conductive semiconductor layer 142, and the first transparent conductive layer 143. Furthermore, the thickness of the gap passivation layer 180 may be greater than the sum of the thicknesses of the second intrinsic semiconductor layer 151, the second conductive semiconductor layer 152, and the second transparent conductive layer 153. For example, the thickness of the gap passivation layer 180 may be from about 200 Å to about 3000 Å. The above thickness range may provide an optimum balance between the lifetime of carriers and manufacturing costs. For example, if the thickness of the gap passivation layer 180 is less than about 200 Å, the lifetime of carriers may decrease. Also, if the thickness of the gap passivation layer 180 exceeds about 3000 Å, manufacturing costs may increase.

FIG. 2 is a graph showing open circuit voltages (Voc) according to thicknesses of a photovoltaic device according to an embodiment. A Voc is measured when no metal electrode is formed. In FIG. 2, a gap passivation layer containing silicon oxide is formed on the semiconductor layer 110, of which both the front surface and the rear surface are planar. FIG. 2 shows a case in which the thickness of the gap passivation layer is about 1000 Å (first and second embodiments) and a case in which the thickness of the gap passivation layer is about 300 Å (third and fourth embodiments).

Referring to FIG. 2, the thicker the gap passivation layer 180 is, the greater the Voc is. Voc is related to lifetime characteristics of a carrier. Accordingly, the thicker the gap passivation layer 180 is, the longer the lifetime of a carrier is.

The width of the gap passivation layer 180 may be from about 0.5 μm to about 500 μm. The above thickness range may provide an optimum balance between forming a high-quality gap passivation layer on the rear surface of the semiconductor substrate and reducing a dead area of the photovoltaic device. For example, if the width of the gap passivation layer 180 is less than about 0.5 μm, it may be difficult to form a high-quality gap passivation layer 180 on the rear surface of the semiconductor substrate 110, and thus, the gap passivation layer 180 may not properly function. On the contrary, if the width of the gap passivation layer 180 exceeds about 500 μm, a dead area of the photovoltaic device may increase. In one embodiment, the smaller the width of the gap passivation layer 180 is, the more efficient the photovoltaic device is. Therefore, the gap passivation layer 180 may be formed to have a width from about 0.5 μm to about 100 μm.

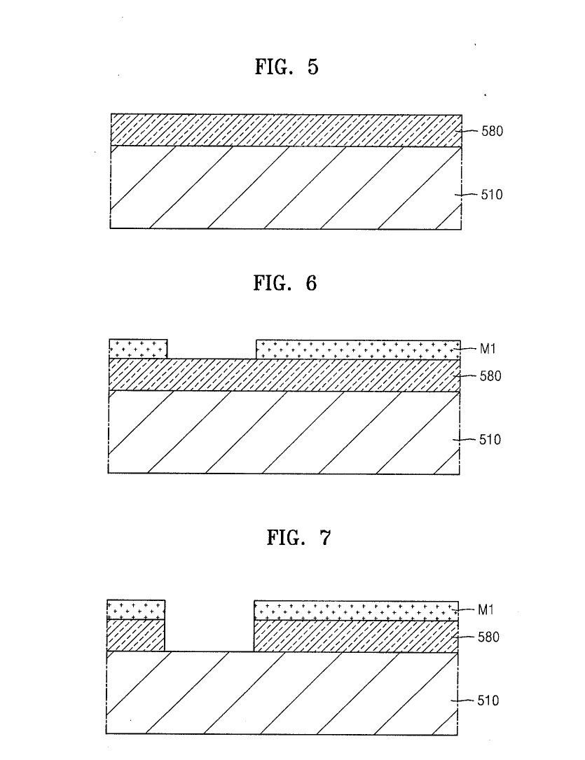

Referring again to FIG. 1, on the gap passivation layer 180, other layers, such as the first and second conductive semiconductor layers 142 and 152, are not formed. It is related with a manufacturing process, and a detailed description thereof will be described below with reference to FIGS. 5 through 30.

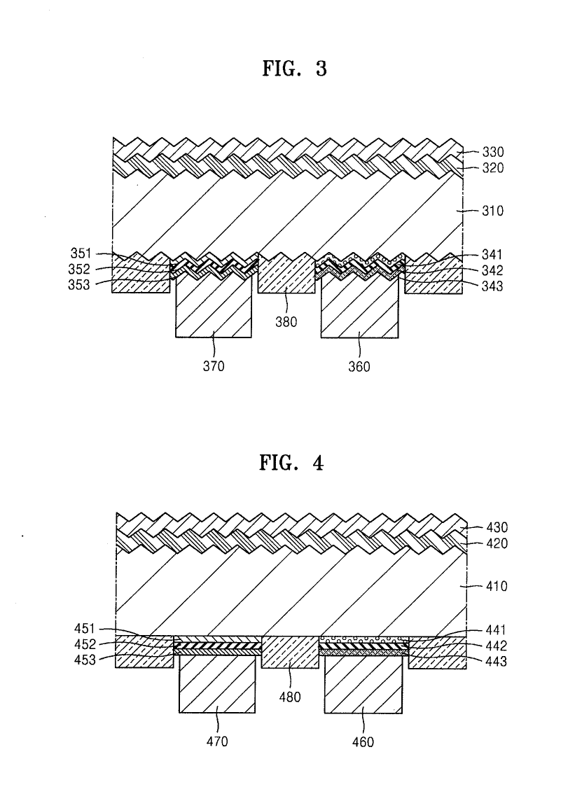

FIGS. 3 and 4 are schematic sectional views of photovoltaic devices according to other embodiments.

Referring to FIG. 3, the photovoltaic device according to the present embodiment includes a semiconductor substrate 310, a front passivation film 320, an anti-reflection film 330, first and second intrinsic semiconductor layers 341 and 351, first and second conductive semiconductor layers 342 and 352, first and second transparent conductive layers 343 and 353, first and second metal electrodes 360 and 370, and a gap passivation layer 380. The configuration of the photovolataic device according to the present embodiment is substantially identical to that of the photovoltaic device described above with reference to FIG. 1.

However, according to the present embodiment, texture structures are formed on the front surface and the rear surface of the semiconductor substrate 310. The texture structures increase optical path length for incident light, thus improving light absorbing efficiency. As an example of texturing processes, the semiconductor substrate 310 may be dipped into a mixture of KOH solution or NaOH solution with isoprophylalcohol (IPA) solution. Accordingly, pyramid-shaped textures may be formed.

In correspondence to the texture structures of the semiconductor substrate 310, the front passivation film 320 and the anti-reflection film 330 may have uneven surfaces. Furthermore, the first and second intrinsic semiconductor layers 341 and 351, the first and second conductive semiconductor layers 342 and 352, and the first and second transparent conductive layers 343 and 353 may have uneven surfaces.

Referring to FIG, 4, the photovoltaic device according to another embodiment includes a semiconductor substrate 410, a front passivation film 420, an anti-reflection film 430, first and second intrinsic semiconductor layers 441 and 451, first and second conductive semiconductor layers 442 and 452, first and second transparent conductive layers 443 and 453, first and second metal electrodes 460 and 470, and a gap passivation layer 480, where the configuration of the photovolataic device according to the present embodiment is substantially identical to that of the photovoltaic device described above with reference to FIG. 1. However, according to the present embodiment, a texture structure may be formed only on the front surface of the semiconductor substrate 410 to improve light absorbing efficiency.

In the FIG. 3 and FIG. 4 embodiments, the first and second intrinsic semiconductor layers 341, 351, 441, and 451 are formed between the semiconductor substrates 310 and 410 and the first and second conductive semiconductor layers 342, 352, 442, and 452 in the photovoltaic devices. However, the first and second intrinsic semiconductor layers 341, 351, 441, and 451 may be omitted.

Hereinafter, a method of manufacturing a photovoltaic device, according to an embodiment is described.

FIGS. 5 through 17 are schematic sectional views showing steps of the method of manufacturing a photovoltaic device according to an embodiment. For convenience of explanation, FIGS. 5 through 17 show that the rear surface of the photovoltaic device faces upward, whereas the front surface of the photovoltaic device faces downward.

First, a semiconductor substrate 510 is prepared. For example, the semiconductor substrate 510 may be an n-type crystalline silicon wafer. A cleaning operation using an acidic or alkalic solution may be performed on the semiconductor substrate 510 to remove physical and chemical impurities on surfaces of the semiconductor substrate 510.

Referring to FIG. 5, a passivation layer 580 is formed on the semiconductor substrate 510. The passivation layer 580 may include at least one of silicon oxide (SiOₓ) and silicon oxynitride (SiOₓN_{y}). The passivation layer 580 may be formed via thermal oxidation or chemical vapor deposition (CVD).

Although not shown, a texture structure may be formed on the front surface of the semiconductor substrate 510 by using the passivation layer 580 as a mask. The front surface of the semiconductor substrate 510 may be etched by using the passivation layer 580 as an etch mask. For example, a texture structure may be formed on the front surface of the semiconductor substrate 510 by anisotropically etching the semiconductor substrate 510 by using an alkalic solution, such as KOH solution or NaOH solution.

Referring to FIG. 6, a first etch resist M1 is formed on the passivation layer 580. The first etch resist M1 may be formed to cover the semiconductor substrate 510 except for a first region. The first etch resist M1 may be formed as an organic film.

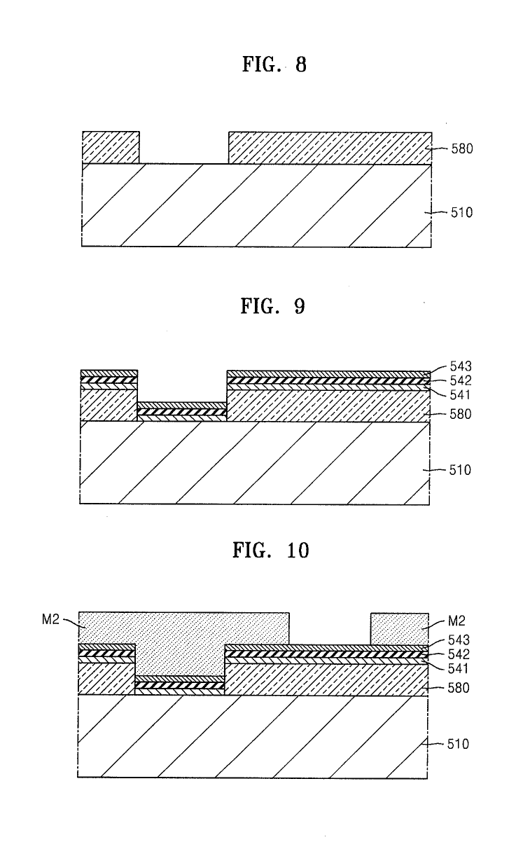

Referring to FIG. 7, the passivation layer 580 is etched by using the first etch resist M1 as an etch mask. Portions of the passivation layer 580 not covered by the first etch resist M1 are removed by an etchant. Examples of the etchants may include hydrofluoric acid (HF), ammonium flouride (NH₄F), or a mixture thereof having etching characteristics with respect to the passivation layer 580. After the passivation layer 580 is etched, the first etch resist M1 is removed as shown in FIG. 8. The first etch resist M1 may be removed by an acetone-based solution or an ethanol-based solution, for example.

Referring to FIG. 9, a first intrinsic semiconductor layer 541, a first conductive semiconductor layer 542, and a first transparent conductive layer 543 are formed on the rear surface of the semiconductor substrate 510.

For example, the first intrinsic semiconductor layer 541 may be formed via CVD using silane (SiH₄), which is a silicon-containing gas, and may be formed of amorphous silicon.

The first conductive semiconductor layer 542 may be doped with a p-type impurity, which is a conductive type opposite to that of the semiconductor substrate 510, may be formed via CVD using silane (SiH₄) and doping gas, such as B₂H₆, and may be formed of amorphous silicon.

The first transparent conductive layer 543 may include a TCO, formed of, for example, ITO, IZO or ZnO, and may be formed via sputtering, e-beam, evaporation, etc.

Referring to FIG. 10, a second etch resist M2 is formed. The second etch resist M2 may be formed to cover the semiconductor substrate 510 except for a second region. The second etch resist M2 may be formed as an organic film.

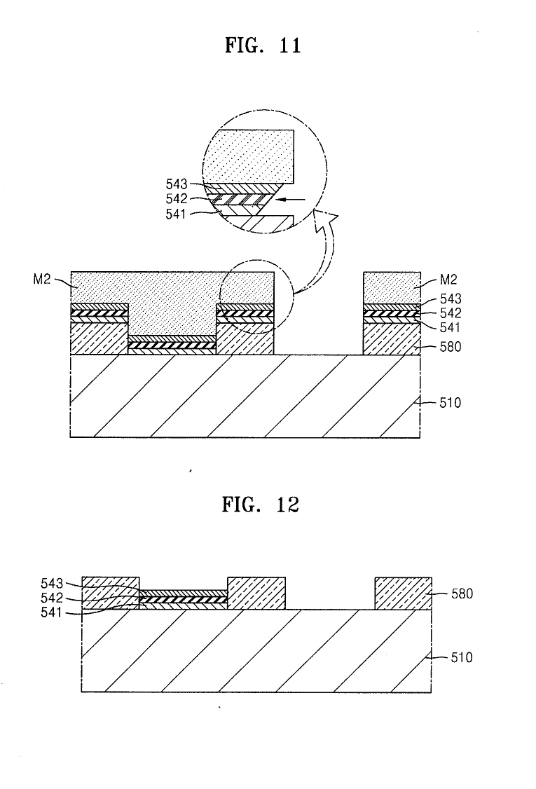

Referring to FIG. 11, the first transparent conductive layer 543, the first conductive semiconductor layer 542, the first intrinsic semiconductor layer 541, and the passivation layer 580 are etched by using the second etch resist M2 as an etch mask to expose the second region of the rear surface of the semiconductor substrate 510.

For example, portions of the first transparent conductive layer 543 not covered by the second etch resist M2 may be removed by an HCl/HNO₃-based etchant. And then, since the first intrinsic semiconductor layer 541 and the first conductive semiconductor layer 542 contain amorphous silicon, portions of the first intrinsic semiconductor layer 541 and the first conductive semiconductor layer 542 not covered by the second etch resist M2 may be removed by an HF/HNO₃-based etchant.

As the first semiconductor layers 541 and 542 are removed, a portion of the passivation layer 580 is exposed and thus is not covered by the second etch resist M2. The exposed portion of the passivation layer 580 may be etched. For example, hydrofluoric acid (HF), ammonium flouride (NH₄F), or a mixture thereof having etching characteristics with respect to the passivation layer 580 may be used.

In one embodiment, as shown in the magnified section of FIG. 11, while the portions not covered by the second etch resist M2 are being removed, the first transparent conductive layer 543 is etched less in the lateral direction than in the thickness direction. On the contrary, the first intrinsic semiconductor layer 541 and the first conductive semiconductor layer 542 including amorphous silicon are etched more in the lateral direction than the first transparent conductive layer 543.

The reason that the first semiconductor layers 541 and 542 formed on the passivation layer 580 are etched more in the lateral direction may be that interface characteristics between the two layers 541 and 542 and the passivation layer 580 differ from interface characteristics between the layers 541 and 542 and the semiconductor substrate 510.

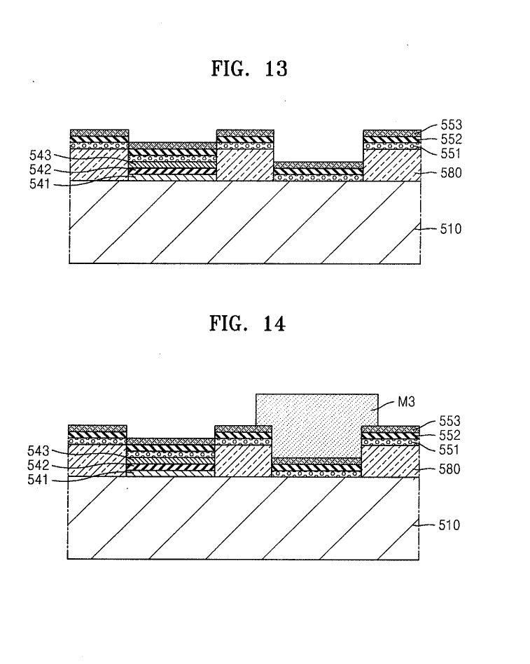

Referring to FIG. 12, the second etch resist M2 is removed. Here, as the second etch resist M2 is removed, portions of the layers 541-543 formed on the passivation layer are also removed. For example, since the first intrinsic semiconductor layer 541 and the first conductive semiconductor layer 542 arranged between the passivation layer 580 and the second etch resist M2 are etched in the lateral direction, the first transparent conductive layer 543 contacting the second etch resist M2 is removed together when the second etch resist M2 is removed, and thus no layer remains on the passivation layer 580. The second etch resist M2 may be removed by an acetone-based solution or an ethanol-based solution, for example.

Referring to FIG. 13, a second intrinsic semiconductor layer 551, a second conductive semiconductor layer 552, and a second transparent conductive layer 553 are formed on the rear surface of the semiconductor substrate 510.

For example, the second intrinsic semiconductor layer 551 may be formed via CVD using silane (SiH₄), which is a silicon-containing gas, and may be formed of amorphous silicon.

The second conductive semiconductor layer 552 may be doped with an n-type impurity, which is the same conductive type as the semiconductor substrate 510, may be formed via CVD using silane (SiH₄) and doping gas, such as PH₃, and may be formed of amorphous silicon.

The second transparent conductive layer 553 may include a TCO, formed of, for example, ITO, IZO or ZnO, and may be formed via sputtering, e-beam, evaporation, etc.

Referring to FIG. 14, a third etch resist M3 is formed. The third etch resist M3 may be formed to cover the second region of the semiconductor substrate 510 and a portion of the passivation layer 580 close to the second region of the semiconductor substrate 510, in consideration of process margin. The third etch resist M3 may be formed as an organic film.

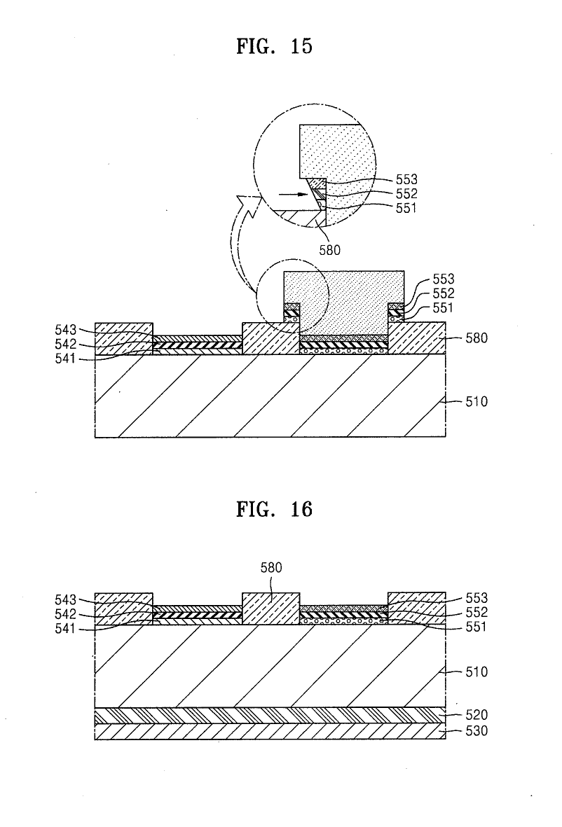

Referring to FIG. 15, the second transparent conductive layer 553, the second conductive semiconductor layer 552, the second intrinsic semiconductor layer 551, and the passivation layer 580 are etched by using the third etch resist M3 as an etch mask.

For example, portions of the second transparent conductive layer 553 not covered by the third etch resist M3 may be removed by an HCl/HNO₃-based etchant. Since the second intrinsic semiconductor layer 551 and the second conductive semiconductor layer 552 contain amorphous silicon, portions of the second intrinsic semiconductor layer 551 and the second conductive semiconductor layer 552 not covered by the third etch resist M3 may be removed by an HF/HNO₃-based etchant.

As the semiconductor layers 551 and 552 are removed, portions of the passivation layer 580 are exposed and thus are not covered by the third etch resist M3. The exposed portions of the passivation layer 580 may be etched. For example, hydrofluoric acid (HF), ammonium flouride (NH₄F), or a mixture thereof having etching characteristics with respect to the passivation layer 580 may be used.

As shown in FIGS. 15 and 16, as the third etch resist M3 is removed, portions of the layers 551-553 (see the magnified section of FIG. 15) formed on the passivation layer 580 are also removed. The reason therefor is as described above with reference to the magnified section of FIG. 11.

Referring to FIG. 16, the third etch resist M3 is removed. As shown in the magnified section of FIG. 15, etching is performed in the lateral direction on the passivation layer 580, no layer remains on the passivation layer 580 after the third etch resist M3 is removed as shown in FIG. 16. The third etch resist M3 may be removed by an acetone-based solution or an ethanol-based solution, for example.

Referring to FIG. 16, a front passivation film 520 and an anti-reflection film 530 are formed on the front surface of the semiconductor substrate 510.

The front passivation film 520 may improve the efficiency of collecting carriers generated by the semiconductor substrate 510 by preventing surface re-combination of the carriers. The front passivation film 520 may be formed of a doped semiconductor film, silicon oxide (SiOₓ), silicon nitride (SiNₓ), etc. For example, the front passivation film 520 may be formed via plasma-enhanced chemical vapor deposition (PECVD). Alternatively, the front passivation film 520 may be doped with an impurity that is denser than the semiconductor substrate 510.

The anti-reflection film 530 may include silicon oxide (SiOₓ), silicon nitride (SiNₓ), silicon oxynitride (SiOₓN_{y}), etc. Alternatively, the anti-reflection film 530 may include titanium oxide (TiO₂), ZnO, zinc sulfide (ZnS), etc. The anti-reflection film 530 may be formed via CVD, sputtering, spin coating, etc.

In the present embodiment, the front passivation film 520 and the anti-reflection film 530 are individually formed. However, a silicon nitride (SiNₓ) film, which may function as both the front passivation film 520 and the anti-reflection film 530, may be formed, as described above.

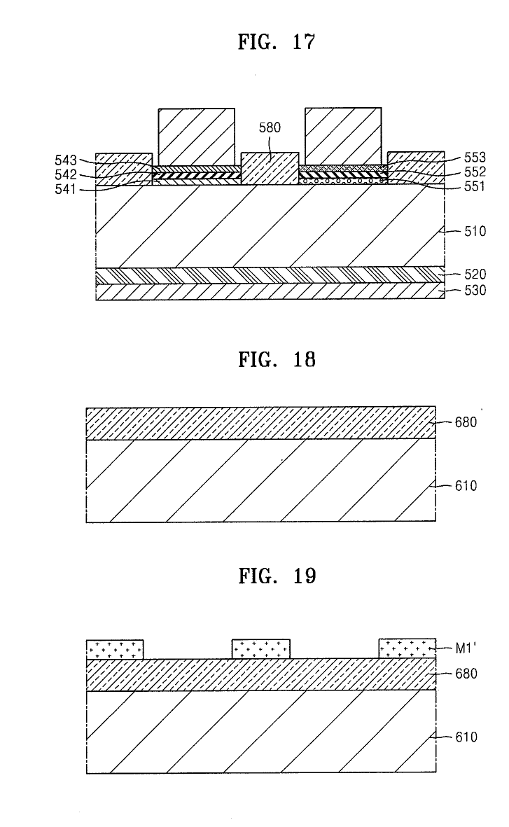

Referring to FIG. 17, first and second metal electrodes 560 and 570 are formed. [We recommend adding reference numerals 560 and 570 to the metal electrodes of FIG. 17] At least one of the first and second metal electrodes 560 and 570 may include silver (Ag), gold (Au), copper (Cu), aluminum (Al), and an alloy thereof. For example, the metal electrodes 560 and 570 may be formed by applying a conductive paste containing the above-stated elements via inkjet printing, gravure printing, offset printing, screen printing, etc. and then firing the conductive paste.

Hereinafter, a method of manufacturing a photovoltaic device according to another embodiment is described.

FIGS. 18 through 30 are schematic sectional views showing steps of the method of manufacturing a photovoltaic device according to another embodiment.

First, a semiconductor substrate 610 is prepared. For example, the semiconductor substrate 610 may be an n-type crystalline silicon wafer. A cleaning operation using an acidic or alkalic solution may be performed on the semiconductor substrate 610 to remove physical and chemical impurities on surfaces of the semiconductor substrate 610.

Referring to FIG. 18, a passivation layer 680 is formed on the semiconductor substrate 610. The passivation layer 680 may include at least one of silicon oxide (SiOₓ) and silicon oxynitride (SiOₓN_{y}). The passivation layer 680 may be formed via thermal oxidation or CVD.

Although not shown, a texture structure may be formed on the front surface of the semiconductor substrate 610 by using the passivation layer 530 as a mask.

Referring to FIG. 19, a first etch resist M1′ is formed on the passivation layer 680. The first etch resist M1′ may be formed to cover the semiconductor substrate 510 except for the first and second regions. The first etch resist M1′ may be formed as an organic film.

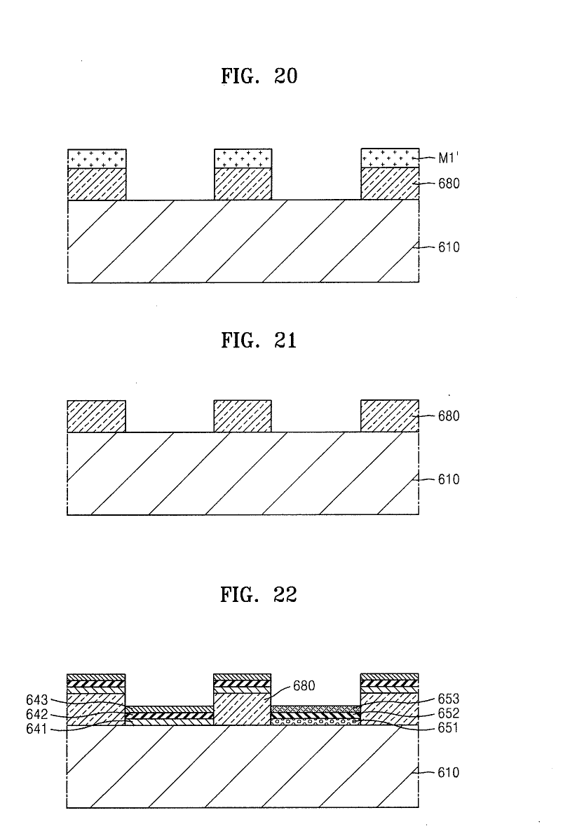

Referring to FIG. 20, the passivation layer 680 is etched by using the first etch resist M1′ as an etch mask. Portions of the passivation layer 680 not covered by the first etch resist M1′ are removed by an etchant. Examples of the etchants may include hydrofluoric acid (HF), ammonium flouride (NH₄F), or a mixture thereof having etching characteristics with respect to the passivation layer 680.

After the passivation layer 680 is etched, the first etch resist M1′ is removed as shown in FIG. 21. The first etch resist MI may be removed by an acetone-based solution or an ethanol-based solution, for example. The passivation layer 680 etched by using the first etch mask M1′ may become the gap passivation layer described above with reference to FIG. 1.

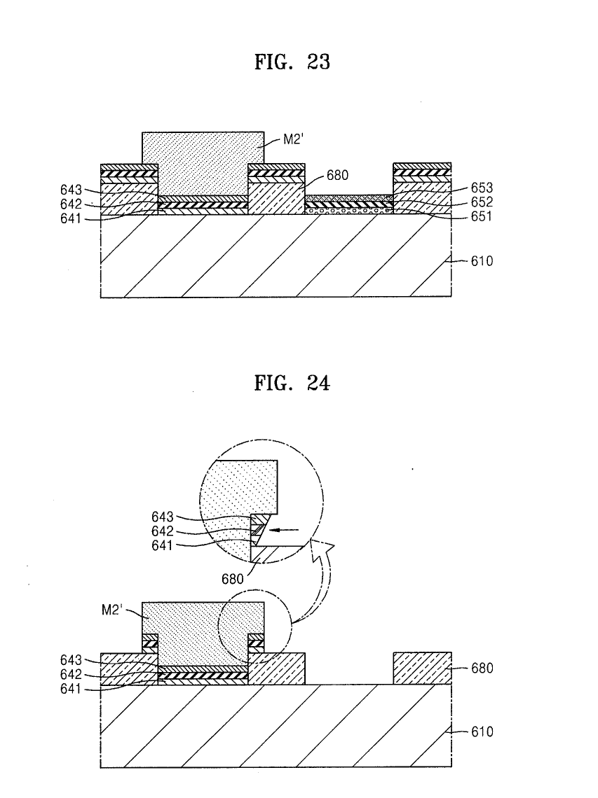

Referring to FIG. 22, a first intrinsic semiconductor layer 641, a first conductive semiconductor layer 642, and a first transparent conductive layer 643 are formed on the rear surface of the semiconductor substrate 610 [It appears that the layers 651-653 shown in FIGS. 22 and 23 should be labeled and drawn as the layers 641-643 (see also FIG. 26). If our understanding is correct, we recommend amending FIGS. 22 and 23 accordingly.]

For example, the first intrinsic semiconductor layer 641 may be formed via CVD using silane (SiH₄), which is a silicon-containing gas, and may be formed of amorphous silicon.

The first conductive semiconductor layer 642 may be doped with a p-type impurity, which is a conductive type opposite to that of the semiconductor substrate 610, may be formed via CVD using silane (SiH₄) and doping gas, such as B₂H₆, and may be formed of amorphous silicon.

The first transparent conductive layer 643 may include a TCO, formed of, for example, ITO, IZO or ZnO, and may be formed via sputtering, e-beam, evaporation, etc.

Referring to FIG. 23, a second etch resist M2′ is formed. The second etch resist M2′ may be formed to cover a portion of the passivation layer 680 close to the first and second regions of the semiconductor substrate 610, in consideration of process margin. The second etch resist M2′ may be formed as an organic film.

Referring to FIG. 24, the first transparent conductive layer 643, the first conductive semiconductor layer 642, the first intrinsic semiconductor layer 641, and the passivation layer 680 are etched by using the second etch resist M2′ as an etch mask.

For example, portions of the first transparent conductive layer 643 not covered by the second etch resist M2′ may be removed by an HCl/HNO₃-based etchant. And then, since the first semiconductor layers 641 and 642 contain amorphous silicon, portions of the layers 641 and 642 not covered by the second etch resist M2′ may be removed by an HF/HNO₃-based etchant.

As the two layers 641 and 642 are removed, portions of the passivation layer 680 are exposed and thus are not covered by the second etch resist M2′. The exposed portions of the passivation layer 680 may be etched. For example, hydrofluoric acid (HF), ammonium flouride (NH₄F), or a mixture thereof having etching characteristics with respect to the passivation layer 680 may be used.

Referring to the magnified section of FIG. 24, while the portions not covered by the second etch resist M2′ are being removed, the first transparent conductive layer 643 is etched less in the lateral direction than in the thickness direction. On the contrary, the semiconductor layers 641 and 642 including amorphous silicon are etched more in the lateral direction than the first transparent conductive layer 643. The reason that the two layers 641 and 642 are etched more in the lateral direction may be based on interface characteristics between i) the layers 641 and 642 and ii) the passivation layer 680, as described above.

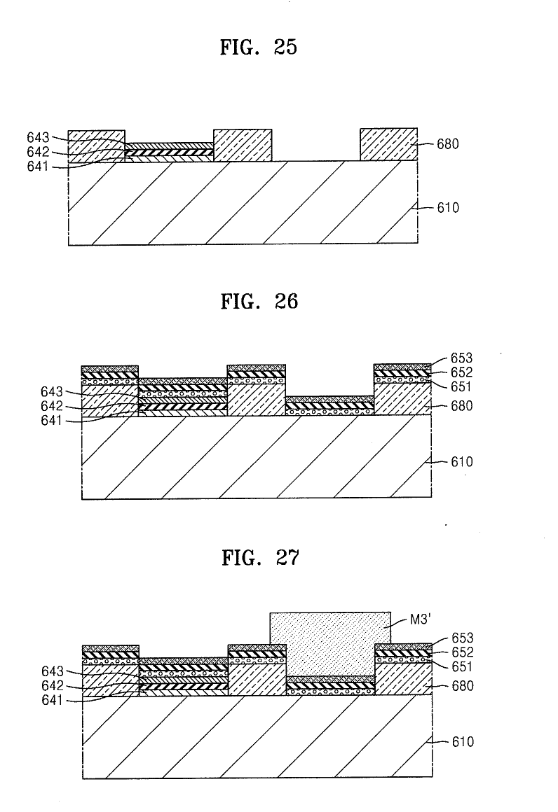

Referring to FIG. 25, the second etch resist M2′ is removed. Here, as the second etch resist M2′ is removed, portions of the three layers 641-643 formed on the passivation layer 680 are also removed. The second etch resist M2′ may be removed by an acetone-based solution or an ethanol-based solution, for example.

Since the layers 641 and 642 arranged between the passivation layer 680 and the second etch resist M2′ are etched in the lateral direction, the first transparent conductive layer 643 contacting the second etch resist M2′ is removed together when the second etch resist M2′ is removed, and thus, no layer remains on the passivation layer 680.

Referring to FIG. 26, a second intrinsic semiconductor layer 651, a second conductive semiconductor layer 652, and a second transparent conductive layer 653 are formed on the rear surface of the semiconductor substrate 610.

For example, the second intrinsic semiconductor layer 651 may be formed via CVD using silane (SiH₄), which is a silicon-containing gas, and may be formed of amorphous silicon.

The second conductive semiconductor layer 652 may be doped with an n-type impurity, which is the same conductive type as the semiconductor substrate 610, may be formed via CVD using silane (SiH₄) and doping gas, such as PH₃, and may be formed of amorphous silicon.

The second transparent conductive layer 653 may include a TCO, formed of, for example, ITO, IZO or ZnO, and may be formed via sputtering, e-beam, evaporation, etc.

Referring to FIG. 27, a third etch resist M3′ is formed. The third etch resist M3′ may be formed to cover the second region of the semiconductor substrate 610 and a portion of the passivation layer 680 close to the second region of the semiconductor substrate 610, in consideration of process margin. The third etch resist M3′ may be formed as an organic film.

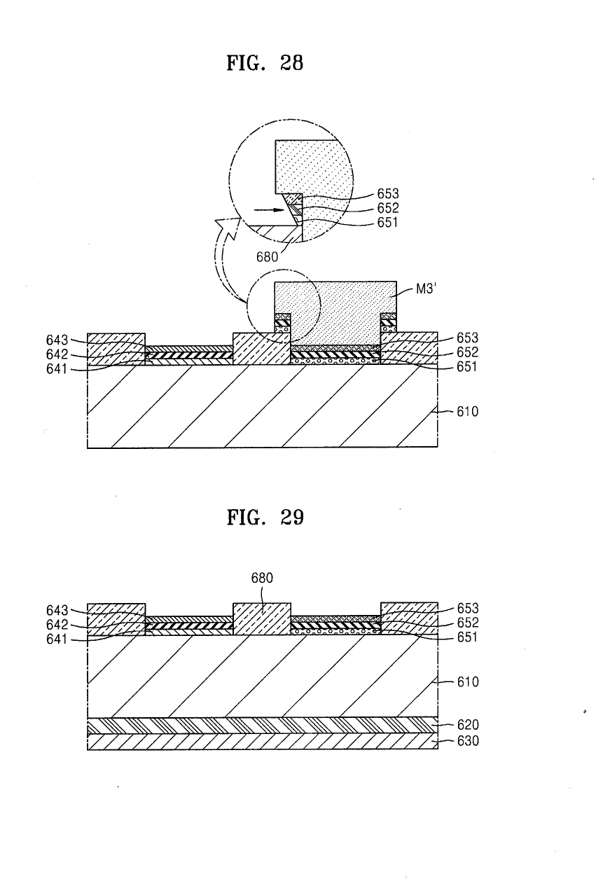

Referring to FIG. 28, the layers 651-653 and the passivation layer 680 are etched by using the third etch resist M3′ as an etch mask.

For example, portions of the second transparent conductive layer 653 not covered by the third etch resist M3′ may be removed by an HCl/HNO₃-based etchant. And then, since the semiconductor layers 651 and 652 contain amorphous silicon, portions of the two layers 651 and 652 not covered by the third etch resist M3′ may be removed by an HF/HNO₃-based etchant.

As the two layers 651 and 652 are removed, portions of the passivation layer 680 are exposed and thus are not covered by the third etch resist M3′. The exposed portions of the passivation layer 680 may be etched. For example, hydrofluoric acid (HF), ammonium flouride (NH₄F), or a mixture thereof having etching characteristics with respect to the passivation layer 680 may be used.

As shown in FIGS. 28 and 29, as the third etch resist M3′ is removed, portions of the layers 651-653 (see the magnified section of FIG. 28) formed on the passivation layer 680 are also removed. The reason therefor is as described above with reference to the magnified section of FIG. 24.

Referring to FIG. 29, the third etch resist M3′ is removed. The second transparent conductive layer 653 on the passivation layer 680, which is hardly etched in the lateral direction, is also removed as the third etch resist M3′ is removed. The third etch resist M3′ may be removed by an acetone-based solution or an ethanol-based solution, for example.

Referring again to FIG. 29, a front passivation film 620 and an anti-reflection film 630 are formed on the front surface of the semiconductor substrate 510.

The front passivation film 620 may improve the efficiency of collecting carriers generated by the semiconductor substrate 610 by preventing surface re-combination of the carriers. The front passivation film 620 may be formed of a doped semiconductor film, silicon oxide (SiOₓ), silicon nitride (SiNₓ), etc. For example, the front passivation film 620 may be formed via PECVD. Alternatively, the front passivation film 620 may be doped with an impurity that is denser than the semiconductor substrate 610.

The anti-reflection film 630 may include silicon oxide (SiOₓ), silicon nitride (SiNₓ), silicon oxynitride (SiOₓN_{y}), etc. Alternatively, the anti-reflection film 630 may include titanium oxide (TiO₂), ZnO, zinc sulfide (ZnS), etc. The anti-reflection film 630 may be formed via CVD, sputtering, spin coating, etc.

In the present embodiment, the front passivation film 620 and the anti-reflection film 630 are individually formed. However, a silicon nitride (SiNₓ) film, which may function as both the front passivation film 620 and the anti-reflection film 630, may be formed, as described above.

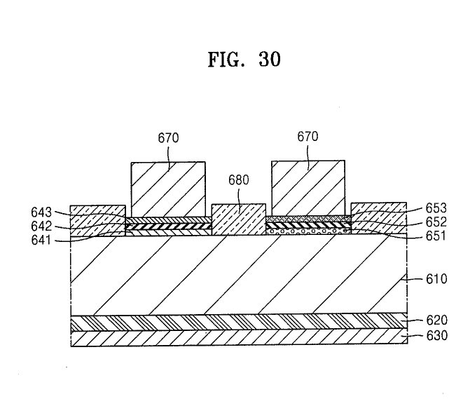

Referring to FIG. 30, first and second metal electrodes 460 and 470 are formed. The first and second metal electrodes 460 and 470 may include silver (Ag), gold (Au), copper (Cu), aluminum (Al), and an alloy thereof. For example, the first and second metal electrodes 460 and 470 may be formed by applying a conductive paste containing the above-stated elements via inkjet printing, gravure printing, offset printing, screen printing, etc. and then firing the conductive paste.

Since an intrinsic semiconductor layer and conductive semiconductor layers arranged between a gap passivation layer and an etch mask are etched in the lateral direction, even if an alignment error of formation of etch resists occurs, an intrinsic semiconductor layer, conductive semiconductor layers, and a transparent conductive layer may be formed only in first and second regions of a semiconductor substrate.

Since the width of a gap passivation layer is determined based on etching (shown in FIGS. 7, 11, and 20), the width of the gap passivation layer may be finely adjusted.

According to at least one of the disclosed embodiments, since intrinsic semiconductor layers and conductive semiconductor layers formed between a gap passivation layer and an etch mask are etched in the lateral direction, an intrinsic semiconductor layer, a conductive semiconductor layer, and a transparent conductive layer may be formed only in first and second regions, even if an alignment error occurs during formation of an etch resist.

Furthermore, since the width of a gap passivation layer is determined by etching a passivation layer, the width of a gap passivation layer may be minutely adjusted.

It should be understood that the disclosed embodiments are considered in a descriptive sense only and not for purposes of limitation. Descriptions of features or aspects within each embodiment should typically be considered as available for other similar features or aspects in other embodiments.

What is claimed is:

1. A photovoltaic device comprising:
a semiconductor substrate;
a first conductive semiconductor layer formed on a first region of the semiconductor substrate, wherein the first conductive semiconductor layer has a conductive type opposite to that of the semiconductor substrate;
a first transparent conductive layer formed on the first conductive semiconductor layer;
a second conductive semiconductor layer formed on a second region of the semiconductor substrate, wherein the second conductive semiconductor layer has a conductive type opposite to the first conductive type;
a second transparent conductive layer formed on the second conductive semiconductor layer; and
a gap passivation layer interposed between i) the first layers and ii) the second layers, wherein the gap passivation layer has a thickness greater than the sum of the thicknesses of the first layers.

2. The photovoltaic device of claim 1, wherein the thickness of the gap passivation layer is greater than the sum of the thicknesses of the second layers.

3. The photovoltaic device of claim 1, wherein the gap passivation layer contacts the semiconductor substrate.

4. The photovoltaic device of claim 1, further comprising a first intrinsic semiconductor layer interposed between the semiconductor substrate and the first conductive semiconductor layer,
wherein the thickness of the gap passivation layer is greater than the sum of the thicknesses of the first layers.

5. The photovoltaic device of claim 1, further comprising a second intrinsic semiconductor layer interposed between the semiconductor substrate and the second conductive semiconductor layer,
wherein the thickness of the gap passivation layer is greater than the sum of the thicknesses of the second layers.

6. The photovoltaic device of claim 1, wherein the width of the gap passivation layer is from about 0.5 μm to about 500 μm.

7. The photovoltaic device of claim 1, wherein the gap passivation layer contacts i) the first and second conductive semiconductor layers and ii) the first and second transparent conductive layers.

8. The photovoltaic device of claim 1, wherein the thickness of the gap passivation layer is from about 200 Å to about 3000 Å.

9. The photovoltaic device of claim 1, wherein the semiconductor substrate comprises crystalline silicon, and wherein at least one of the first and second conductive semiconductor layers comprises amorphous silicon.

10. The photovoltaic device of claim 1, wherein the gap passivation layer is formed of at least one of silicon oxide (SiOₓ) and silicon oxynitride (SiOₓN_{y}).

11. A method of manufacturing a photovoltaic device, the method comprising:
forming a passivation layer over a semiconductor substrate;
opening a first region of the passivation layer such that a first portion of the semiconductor substrate is exposed;
sequentially forming a first intrinsic semiconductor layer, a first conductive semiconductor layer, and a first transparent conductive layer on the first exposed portion of the semiconductor substrate and the passivation layer;
forming a first etch resist on the passivation layer except for a second region spaced apart from the first region;
opening the second region of the passivation layer based on etching of the passivation layer with the use of the first etch resist as an etch mask such that a second portion of the semiconductor substrate is exposed;
removing the first etch resist;
sequentially forming a second intrinsic semiconductor layer, a second conductive semiconductor layer, and a second transparent conductive layer on i) the second exposed portion of the semiconductor substrate, ii) the passivation layer and iii) the first transparent conductive layer;
forming a second etch resist to cover the second region;
etching the second intrinsic semiconductor layer, the second conductive semiconductor layer, and the second transparent conductive layer with the use of the second etch resist as an etch mask; and
removing the second etch resist.

12. The method of claim 11, wherein the first intrinsic semiconductor layer, the first conductive semiconductor layer, and the first transparent conductive layer are sequentially formed such that the sum of the thicknesses of the first layers is less than the thickness of the passivation layer, and
wherein the second intrinsic semiconductor layer, the second conductive semiconductor layer, and the second transparent conductive layer are sequentially formed such that the sum of the thicknesses of the second layers is less than the thickness of the passivation layer.

13. The method of claim 11, wherein the opening of the second region comprises:
etching a portion of the first transparent conductive layer which is not covered by the first etch resist;
laterally etching portions of the first semiconductor layers which are interposed between the passivation layer and the etched portion of the first transparent conductive layer; and
etching a portion of the passivation layer which is formed substantially directly below the etched portions of the first semiconductor layers.

14. The method of claim 13, wherein the first semiconductor layers are etched more than the first transparent conductive layer.

15. The method of claim 11, wherein the etching of the second layers comprises:
etching a portion of the second transparent conductive layer which is not covered by the second etch resist; and
laterally etching portions of the second semiconductor layers, which are interposed between the passivation layer and the etched portion of the second transparent conductive layer,
wherein the second semiconductor layers are etched more than the first transparent conductive layer.

16. A method of manufacturing a photovoltaic device, the method comprising:
providing a passivation layer over a semiconductor substrate;
opening first and second regions of the passivation layer such that first and second portions of the semiconductor substrate are exposed, wherein the second region is spaced apart from the first region;
sequentially forming a first conductive semiconductor layer and a first transparent conductive layer on the first and second exposed portions of the semiconductor substrate and the passivation layer;
forming a first etch resist to cover the first region;
etching the first conductive semiconductor layer and the first transparent conductive layer with the use of the first etch resist as an etch mask;
removing the first etch resist;
sequentially forming a second conductive semiconductor layer and a second transparent conductive layer on i) the second exposed portion of the semiconductor substrate, ii) the passivation layer and iii) the first transparent conductive layer;
forming a second etch resist to cover the second region;
etching the second conductive semiconductor layer, and the second transparent conductive layer with the use of the second etch resist as an etch mask; and
removing the second etch resist.

17. The method of claim 16, wherein the first conductive semiconductor layer and the first transparent conductive layer are sequentially formed such that the sum of the thicknesses of the first layers is less than the thickness of the passivation layer, and
wherein the second conductive semiconductor layer and the second transparent conductive layer are sequentially formed, such that the sum of the thicknesses of the second layers is less than the thickness of the passivation layer.

18. The method of claim 16, wherein the etching of the first layers comprises:
etching a portion of the first transparent conductive layer which is not covered by the first etch resist; and
laterally etching a portion of the first conductive semiconductor layer formed between the etched portion of the first transparent conductive layer and the passivation layer.

19. The method of claim 18, wherein the first conductive semiconductor layer is etched more than the first transparent conductive layer.

20. The method of claim 16, wherein the etching of the second layers comprises:
etching a portion of the second transparent conductive layer which is not covered by the second etch resist; and
laterally etching a portion of the second conductive semiconductor layer formed between the etched portion of the second transparent conductive layer and the passivation layer,
wherein the second conductive semiconductor layer is etched more than the first transparent conductive layer.
